(19) United States
(12) Patent Application Publication
(10) Pub. No.: US 2025/0228027 A1
(43) Pub. Date: Jul. 10, 2025

(54) SEMICONDUCTOR STRUCTURE INCLUDING IMAGE SENSOR AND MRAM DEVICE

(71) Applicant: TAIWAN SEMICONDUCTOR MANUFACTURING COMPANY LTD., HSINCHU (TW)

(72) Inventors: YU-FANG CHIU, TAIPEI CITY (TW); KE-JING YU, KAOHSIUNG CITY (TW); ANHAO CHENG, TAICHUNG CITY (TW)

(21) Appl. No.: 18/403,774

(22) Filed: Jan. 4, 2024

(51) Int. Cl. H01L 27/146; H01L 23/522; H01L 23/528; H10B 61/00

(52) U.S. Cl. CPC H10F 39/811; H01L 23/5226; H01L 23/5283; H10B 61/22; H10F 39/026; H10F 39/199; H10F 39/8037

(57) ABSTRACT

The semiconductor structure includes a substrate, an interconnect structure, a pixel structure, a memory device and a logic device. The interconnect structure is disposed over a front-side of the substrate. The pixel structure includes an image sensor, disposed in a backside of the substrate and configured to receive an optical signal from the backside of the substrate; and a pixel transistor array, disposed in the substrate and adjacent to the image sensor. The memory device includes a memory transistor, disposed in the substrate; and a MRAM unit, disposed in the interconnect structure and over the memory transistor. The logic device is disposed in the substrate and configured to process an electrical signal generated by the optical signal from the image sensor.

### BACKGROUND

Digital cameras and other imaging devices employ images sensors. Image sensors convert optical images to digital data that may be represented as digital images. One type of image sensor commonly used in optical imaging devices is a back side illumination (BSI) image sensor. BSI image sensor fabrication can be integrated into conventional semiconductor processes for low cost, small size, and high integration. Further, BSI image sensors have low operating voltage, low power consumption, high quantum efficiency, low read-out noise, and allow random access. As the semiconductor industry growth, a demand on high quality and high speed of image throughput has been encountered.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, dimensions of the various features may be arbitrarily increased or reduced for clarity of discussion.

FIG. 1 is a schematic cross-sectional diagram of a semiconductor structure in accordance with some embodiments of the present disclosure.

FIG. 2 is a schematic cross-sectional diagram of a portion of the semiconductor structure shown in FIG. 1 in accordance with some embodiments of the present disclosure.

FIGS. 3 to 8 are schematic cross-sectional diagrams of semiconductor structures in accordance with different embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context. In addition, the term “source/drain region” or “source/drain regions” may refer to a source or a drain, individually or collectively dependent upon the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from normal deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages, such as those for quantities of materials, durations of time, temperatures, operating conditions, ratios of amounts, and the likes thereof disclosed herein, should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

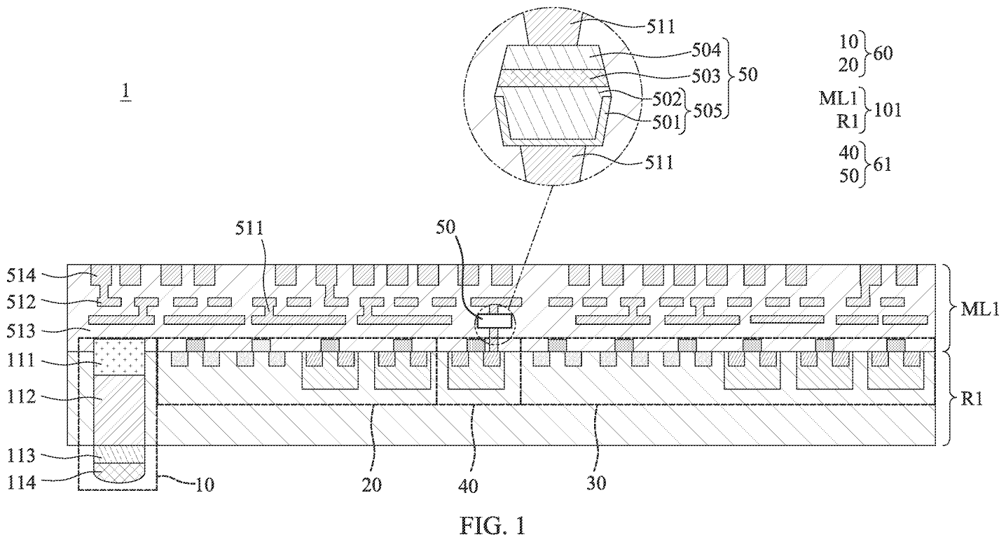

FIG. 1 is a schematic cross-sectional diagram of a semiconductor structure 1 in accordance with some embodiments of the present disclosure. The semiconductor structure 1 can be a photonic device including a MRAM device integrated in a same wafer. The semiconductor structure 1 may include a substrate R1 and an interconnect structure ML1 disposed over a front-side of the substrate R1.

The substrate R1 can be a semiconductive layer, which may include a bulk semiconductor material, such as silicon, or other semiconductor materials, such as silicon germanium, silicon carbide, gallium arsenide, or the like. The substrate R1 may be of a first conductivity type, e.g., a P-type semiconductive substrate (acceptor type), or a second conductivity type, e.g., an N-type semiconductive substrate (donor type).

The interconnect structure ML1 includes a plurality of conductive features (including metal via features 511 and metal line features 512) surrounded by a plurality of intermetal dielectric (IMD) layers 513. In some embodiments, the IMD layer 513 is directly over the substrate R1. In some embodiments, an insulating layer (not shown in the figures) is disposed over the substrate R1 covering transistors formed thereon, and the interconnect structure ML1 is formed over the insulating layer. In some embodiments, the insulating layer includes a dielectric material same as that of the IMD layers 513. In some embodiments, the conductive features include tungsten (W), aluminum (Al), copper (Cu), silver (Ag), gold (Au), titanium (Ti), tantalum (Ta), ruthenium (Ru), titanium-nitride (TiN), tantalum-nitride (TaN), ruthenium nitride (RuN), tungsten nitride (WN), and alloys thereof.

The conductive features include a plurality of metal line layers M0 to Mn, wherein n is a positive integer greater than 1, and a plurality of metal via layers, alternately arranged between the plurality of metal line layers M0 to Mn for electrical connection between the metal line layers. The metal line layer M0 may be the first metal line layer over the substrate R1, and the metal line layer Mn may be the topmost metal line layer of the interconnect structure ML1. Each of the metal line layers M0 to Mn includes a plurality of metal line features 512, and each of the metal via layers includes a plurality of metal via features 511. The metal line features 512 in the topmost metal line layer Mn can be used for hybrid bonding to another substrate, wafer, chip, die, or device. In addition, the topmost metal line layer Mn may include a plurality of dummy metal line features or dummy metal segments being electrically isolated from other conductive features fur a purpose of hybrid bonding. For a purpose illustration, the metal line features 512 in the topmost metal line layer Mn is referred to as metal line features 514. It should be noted that a number of metal line layers can be adjusted according to different applications, and the disclosure is not limited to a number of metal line layers shown in the features.

A backside image (BSI) sensor 10 is formed or disposed in the substrate R1 (e.g., a backside of the substrate R1). The BSI sensor 10 is configured to receive an optical signal from a backside of the substrate R1. In some embodiments, the BSI sensor 10 includes a transistor region 111, a sensing region 112, a color filter 113 and a micro-lens 114. In some embodiments, the transistor region 111 includes at least a transistor. In some embodiments, the sensing region 112 including one or more doping regions in the substrate R1. In some embodiments, the sensing region 112 and the transistor region 111 together define one or more of photodiodes. In some embodiments, the color filter 113 can be a red, green, or blue color filter. FIG. 1 shows one BSI sensor 10 (including the micro-lens 114, the color filter 113, the sensing region 112 and the transistor region 111) with a red filter for a purpose of illustration. The semiconductor structure 1 can include multiple BSI sensor 10. In some embodiments, the BSI sensor 10 is formed from the backside of the substrate R1.

A pixel transistor array 20 is formed in the substrate R1 adjacent to the BSI sensor 10. The pixel transistor array 20 may include multiple transistors for processing an electrical signal generated by the photodiodes from the optical signal received by the BSI sensor 10. In some embodiments, the electrical signal generated by the photodiodes is transmitted to the pixel transistor array 20 through the interconnect structure ML1. In some embodiments, the pixel transistor array 20 may be directly adjacent to the BSI sensor 10 for a purpose of short distance and less signal loss. The pixel transistor array 20 can include different conductive types of transistors as shown in FIG. 1. It should be noted that a type of the transistors in the pixel transistor array 20 and a number of transistors of the pixel transistor array 20 can be adjusted according to different embodiments, and those are not limited herein. In some embodiments, one pixel transistor array 20 is to one BSI sensor 10. In some embodiments, one pixel transistor array 20 includes 3-6 pixel transistors. In some embodiments, one or multiple BSI sensors 10 and one pixel transistor array 20 together forms a pixel structure 60. In some embodiments, the pixel structure 60 is one bit pixel. In some embodiments, the pixel transistor array 20 horizontally overlaps the transistor region 111 of the BSI sensor 10.

A logic device 30 is formed in the substrate R1 and configured to process an electrical signal from the pixel structure 60. Electrical signals from the pixel structure 60 are transmitted to the logic device 30 through the interconnect structure ML1. The logic device 30 can be an array of transistors. The transistors of the logic device 30 can include one or more transistors, such as planar transistor, a multi-gate transistor, a gate-all-around field-effect transistor (GAAFET), a fin field-effect transistor (FinFET), a vertical transistor, a nanosheet transistor, a nanowire transistor, a bipolar junction transistor (BJT), a high-electron-mobility transistor (HEMT or HEM FET), a selector (including Ovonic threshold switching or tunneling types), or a combination thereof. Similarly, the transistors of the pixel transistor array 20 can be one or more of the above listed types of transistors. In some embodiments, the transistors of the pixel transistor array 20 and the transistors of the logic device 30 includes a same type/generation of transistor. For a purpose of illustration, each of the transistors of the pixel transistor array 20 and the logic device 30 are depicted in the figures as a planar transistor including a pair of source/drain structures formed in the substrate R1 and a gate structure formed on the substrate R1 and between the pair of source/drain structures. However, the present disclosure is not limited thereto.

A memory device 61 includes a memory transistor 40 and a MRAM (Magnetoresistive Random Access Memory) unit 50. The memory transistor 40 may be formed or disposed in the substrate R1. In some embodiments, the memory transistor 40 is at an elevation of the transistor region 111, the logic device 30 or the pixel transistor array 20. In some embodiments, the memory transistor 40 horizontally overlaps at least one of the transistor region 111, the logic device 30 and the pixel transistor array 20. In some embodiments, the memory transistor 40 is formed concurrently with the transistors of the logic device 30 or the transistors of the pixel transistor array 20. The MRAM unit 50 can be formed in the interconnect structure ML1 above the memory transistor 40. In some embodiments, the MRAM unit 50 vertically overlaps the memory transistor 40. In some embodiments, the MRAM unit 50 is within an area of vertical projection of the memory transistor 40. In some embodiments, the MRAM unit 50 is at an elevation above an elevation of the transistor region 111, the logic device 30, or the pixel transistor array 20. For a purpose of electrical connection and less signal loss, the MRAM unit 50 may be disposed in a metal line layer or between metal line layers close to the substrate R1. For example, the MRAM unit 50 is disposed in one of the metal line layers M3 to M6.

The memory device 61 can be configured to store information from the pixel structure 60 or to store information from the logic device 30, and a position of the memory device 61 in the substrate R1 can be designed according to the purpose of the memory device 61. In some embodiments, the memory device 61 electrically connects to the pixel structure 60 through the interconnect structure ML1 for storing information from the pixel structure 60. In such embodiments, it is designed to have a distance between the memory device 61 and the pixel structure 60 as short as possible. In some embodiments, the distance between the memory device 61 and the pixel structure 60 is less than a distance between the memory device 61 and the logic device 30. In other embodiments, the memory device 61 electrically connects to the logic device 30 through the interconnect structure ML1 for storing information from the logic device 30. In such embodiments, it is designed to have a distance between the memory device 61 and the logic device 30 as short as possible. In some embodiments, the distance between the memory device 61 and the logic device 30 is less than a distance between the memory device 61 and the pixel structure 60.

The MRAM unit 50 may include a bottom electrode 505, a top electrode 504 and a memory element 503 disposed between the top electrode 504 and the bottom electrode 505. The top electrode 504 and the bottom electrode 505 are conductive, and may include, for example, metals, metal nitrides, or other suitable conductive materials. For example but not limited thereto, the top electrode 504 and the bottom electrode 505 can include copper (Cu), tantalum (Ta), tantalum nitride (TaN), titanium (Ti), titanium nitride (TiN), tungsten (W), tungsten nitride (WN), ruthenium (Ru), platinum (Pt), palladium (Pd), nickel (Ni), nickel chromium (NiCr), zirconium (Zr), or niobium (Nb). Each of the top electrode 504 and the bottom electrode 505 may include one or more conductive layers. In some embodiments, the top electrode 504 is a single layer of conductive material. In some embodiments, the bottom electrode 505 include two layers 501 and 502 of different conductive materials. The bottom electrode 505 may electrically connect to a drain structure of the memory transistor 40. In some embodiments, the bottom electrode 505 electrically connects to the drain structure of the memory transistor 40 through a metal via feature 511. In some embodiments, the bottom electrode 505 electrically connects to a metal line feature 512 in a lower metal line layer through a metal via feature 511, and the top electrode 504 electrically connects to another metal line feature 512 in an upper metal line layer through another metal via feature 511.

The memory element 503 may include an array of densely-packed MRAM cells. In each MRAM cell, a data-storage element, such as a magnetic tunneling junction (MTJ) element, may be integrated with the memory transistor 40 to perform write and read operations. The MTJ element may be fabricated by patterning a MTJ stack disposed between the bottom electrode 505 and the top electrode 504 with photolithography. The MTJ stack includes a reference layer and a free layer separated by a tunnel barrier layer (TBL). The reference layer and the free layer can include one or more ferromagnetic materials. In some embodiments, the reference layer is a multi-layer structure. In some embodiments, the reference layer includes a ferromagnetic iron-boron (Fe—B) film, a nonmagnetic molybdenum (Mo) film, a ferromagnetic cobalt (Co) film, or a combination thereof. In some embodiments, the free layer is a multi-layer structure. In some embodiments, the reference layer includes a first ferromagnetic cobalt-iron-boron (Co—Fe—B) film, a nonmagnetic Mo film and a second ferromagnetic Co—Fe—B film.

A layout of the memory device 61 (from a top-view perspective) may include the memory transistor 40 and an isolation surrounding the memory transistor 40. In some embodiments, a size of the layout of the memory device 61 can be measured according to a layout of the memory transistor 40. A layout of the pixel structure 60 (from a top-view perspective) may include the BSI sensor 10, the pixel transistor array 20, and an isolation surrounding the pixel transistor array 20. In some embodiments, a size of the layout of the memory device 61 is less than a size of the layout of the pixel structure 60. In some embodiments, a diameter (or a length) of the layout of the memory device 61 is less than 100 nanometers (nm). In some embodiments, a diameter (or a length) of the layout of the pixel structure 61 is less than 2000 nm. A layout and a size of the layout of the logic device 30 can depend on a specification of an application, and are not limited herein.

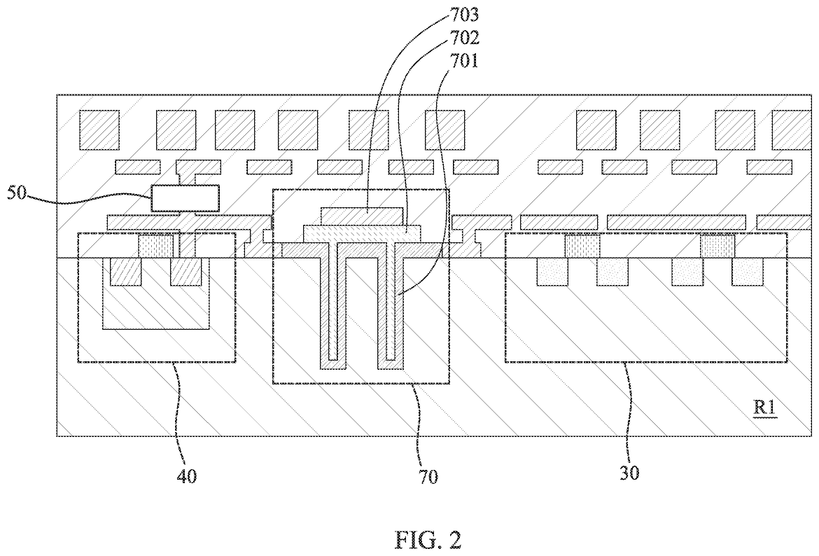

FIG. 2 is a schematic cross-sectional diagram of a portion of the semiconductor structure 1 in accordance with some embodiments of the present disclosure. In some embodiments, the semiconductor structure 1 further includes a deep trench (DT) capacitor 70 disposed in the substrate R1. The DT capacitor 70 may be disposed at an elevation of the pixel transistor array 20, the transistor region 111, the memory transistor 40, or the logic device 30. In some embodiments, the DT capacitor 70 is disposed horizontally adjacent to the memory transistor 40. In some embodiments, the DT capacitor 70 is disposed between the memory transistor 40 and the logic device 30. The DT capacitor 70 includes a lower electrode 701, a dielectric layer 702, and an upper electrode 703. A number of vertical extensions and a depth of a vertical extension of the DT capacitor 70 can be adjusted according to a designed capacity. The DT capacitor 70 is for a purpose of providing electricity to the memory transistor 40 when the semiconductor structure 1 is electrically disconnected to a power source. In some embodiments, the DT capacitor 70 is electrical connected to the memory transistor 40 (e.g., DT capacitor 70 can provide voltages for both gate and drain of the memory transistor 40) through the interconnect structure ML1. A number of the DT capacitors 70 can be adjusted according to a capacitance of the DT capacitor 70 and a number of the memory devices 61. In some embodiments, one DT capacitor 70 is electrically connected to multiple memory devices 61.

As the semiconductor industry growth, a demand on high quality and high speed of image throughput has been encountered, and a traditional image sensor is not sufficient to provide high quality and high speed of image throughput. The present disclosure provides a semiconductor structure with integrated MRAM device and BSI sensor can provide improved quality and speed of image throughput. In the above illustration, embodiments of a MRAM device is integrated with a BSI sensor a logic device in a same wafer are provided. However, the present disclosure is not limited thereto. In other embodiments, the MRAM can be integrated in a two-wafer stacking structure or a three-wafer stacking structure.

For a purpose of clarity and simplicity, reference numbers of elements with same or similar functions are repeated in different embodiments. However, such usage is not intended to limit the present disclosure to specific embodiments or specific elements. In addition, conditions or parameters illustrated in different embodiments can be combined or modified to form different combinations of embodiments as long as the parameters or conditions used are not in conflict.

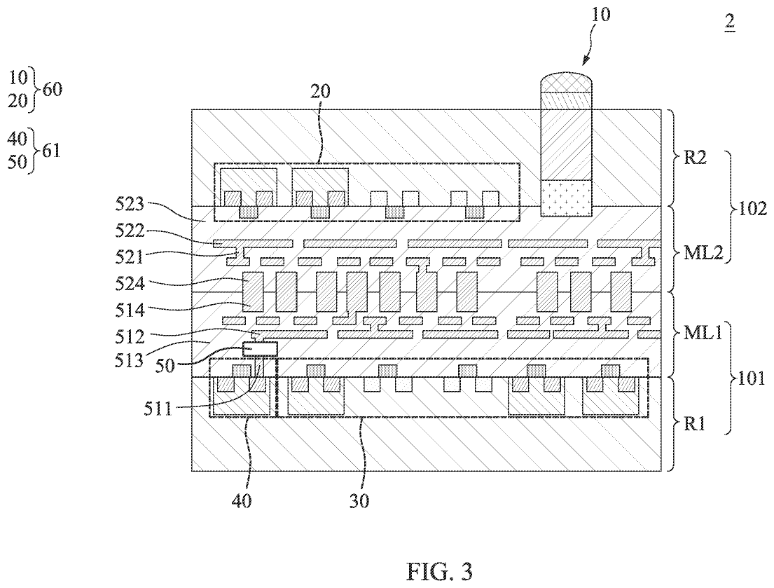

FIG. 3 is a schematic cross-sectional diagram of a semiconductor structure 2 in accordance with some embodiments of the present disclosure. The semiconductor structure 2 is a two-wafer stacking structure. In some embodiments, the semiconductor structure 2 includes a first wafer 101 and a second wafer 102 bonding to the first wafer 101. Each of the first wafer 101 and the second wafer 102 includes a substrate (e.g., R1 and R2 respectively) and an interconnect structure (e.g., ML1 and ML2 respectively) disposed over the substrate. In some embodiments, the first wafer 101 and the second wafer 102 are bonded face-to-face. In some embodiments, the interconnect structure ML1 bonds to the interconnect structure ML2 thereby bonding the first wafer 101 and the second wafer 102. In some embodiments, a bonding interface is located between the interconnect structures ML1 and ML2. The interconnect structure ML2 may include metal via features 521, metal line features 522, IMD layers 523, and metal line features 524 for purpose of hybrid bonding operation. The metal via features 521, metal line features 522, IMD layers 523, and metal line features 524 respectively can be similar to the metal via features 511, metal line features 122, IMD layers 513, and metal line features 514 as illustrated above but with different electrical routing. In some embodiments, the first wafer 101 is a logic wafer, which includes a logic device 30 in the substrate R1. In some embodiments, the second wafer 102 is a sensing wafer, which includes at least a pixel structure 60 in the substrate R2. In some embodiments, the logic device 30 is vertically overlapped by the pixel structure 60. In some embodiments, the logic device 30 is vertically overlapped by at least one of the pixel transistor array 20 and the BSI sensor 10 of the pixel structure 60.

The memory device 61 can be disposed in the first wafer 101 and horizontally adjacent to the logic device 30. In some embodiments, a MRAM unit 50 is disposed between the substrates R1 and R2 along a vertical direction and is proximal to the substrate R1. In some embodiments, the MRAM unit 50 is vertically overlapped by the pixel transistor array 20 and vertically overlaps a memory transistor 40 of the memory device 61. In some embodiments, the memory transistor 40 is at an elevation same as an elevation of the logic device 30 and different from an elevation of the pixel transistor array 20 or the BSI sensor 10. In some embodiments, the memory transistor 40 is vertically overlapped by the pixel transistor array 20. However, the present disclosure is not limited thereto. In other embodiments, the memory transistor 40 is vertically overlapped by the BSI sensor 10. A relative position of the memory transistor 40 to the logic device 30 can be vary as long as the memory transistor 40 and the logic device 30 are both formed in the substrate R1. In some embodiments, the MRAM unit 50 is vertically overlapped by the BSI sensor 10 and vertically overlaps a memory transistor 40 of the memory device 61.

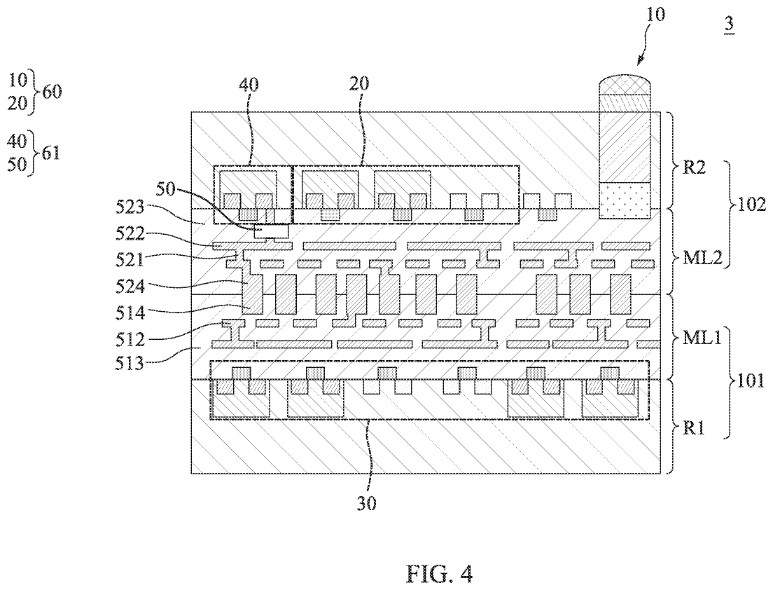

FIG. 4 is a schematic cross-sectional diagram of a semiconductor structure 3 in accordance with some embodiments of the present disclosure. The semiconductor structure 3 can be similar to the semiconductor structure 2 but with a memory device 61 disposed in the second wafer 102. In some embodiments, a memory transistor 40 of the memory device 61 horizontally overlaps the pixel transistor array 20 and a transistor region 111 of the BSI sensor 10. In some embodiments, a MRAM unit 50 is disposed between the substrates R1 and R2 along a vertical direction and is proximal to the substrate R2. In some embodiments, the MRAM unit 50 is vertically overlapped by the memory transistor 40 and vertically overlaps a pixel transistor array 20. In some embodiments, the memory transistor 40 is vertically over and overlaps the logic device 30 in the first wafer 101. In some embodiments, the logic device 30 in the first wafer 101 is overlapped by the memory device 61 and the pixel structure 60.

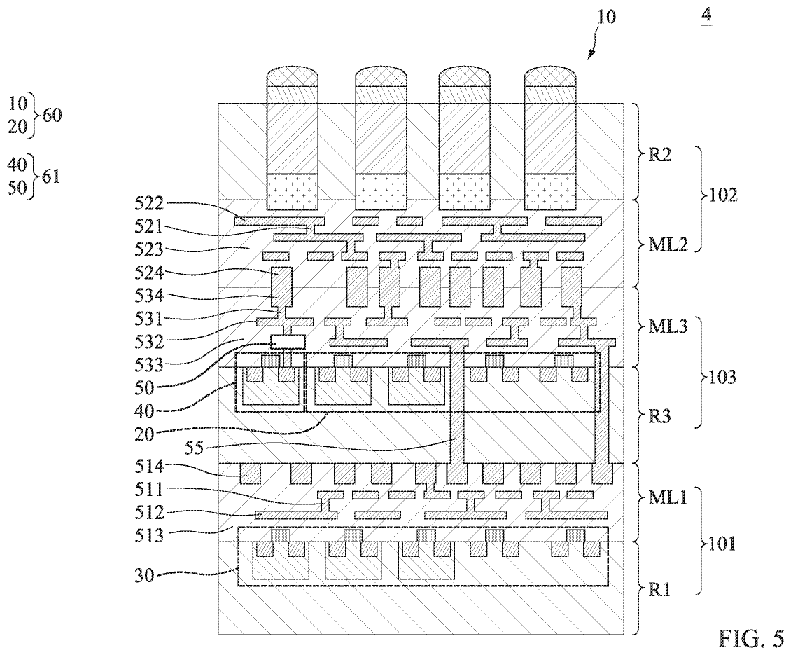

FIG. 5 is a schematic cross-sectional diagram of a semiconductor structure 4 in accordance with some embodiments of the present disclosure. The semiconductor structure 5 is a three-wafer stacking structure. In some embodiments, the semiconductor structure 4 includes a first wafer 101, a second wafer 102, and third wafer 103 disposed between the first wafer 101 and the second wafer 102. The first wafer 101 of the semiconductor structure 4 can be similar to the first wafer 101 of the semiconductor structure 3, and the second wafer 102 of the semiconductor structure 4 can be similar to the second wafer 102 of the semiconductor structure 3 but without the memory device 61 and the pixel transistor array 20. In some embodiments, the memory device 61 and the pixel transistor array 20 are integrated in the third wafer 103.

In some embodiments, the first wafer 101 bonds to the third wafer 103 at a front side of the first wafer 101. In some embodiments, the third wafer 103 bonds to the first wafer 101 at a backside of the third wafer 101. In some embodiments, a bonding interface is located between an interconnect structure ML1 of the first wafer 101 and a substrate R3 of the third wafer 103. A suitable bonding operation, such as a hybrid bonding operation or a fusion bonding operation, can be performed to bond the first wafer 101 and the third wafer 103. In some embodiments, the second wafer 102 bonds to the third wafer 103 at a front side of the second wafer 102. In some embodiments, the third wafer 103 bonds to the second wafer 102 at a front side of the third wafer 103. In some embodiments, a bonding interface is defined between an interconnect structure ML2 of the second wafer 102 and an interconnect structure ML3 of the third wafer 103. A suitable bonding operation, such as a hybrid bonding operation, can be performed to bond the first wafer 101 and the third wafer 103. The BSI sensor 10 can electrically connect to the pixel transistor array 20 through the interconnect structures ML2 and ML3.

The memory transistor 40 and the pixel transistor array 20 may be disposed the substrate R3 of the third wafer 103 between the first wafer 101 and the second wafer 102 along a vertical direction. In some embodiments, a memory transistor 40 is horizontally aligned with the pixel transistor array 20. In some embodiments, the memory transistor 40 is vertically overlapped by a BSI sensor 10 in a substrate R2 of the second wafer 102. In some embodiments, the memory transistor 40 vertically overlaps by the logic device 30 in a substrate R1 of the first wafer 101. In some embodiments, a MRAM unit 50 is disposed in an interconnect structure ML3 of the third wafer 103 and vertically between the memory transistor 40 and the BSI sensor 10. In some embodiments, the MRAM unit 50 vertically overlaps the logic device 30.

The semiconductor structure 4 may further include a through substrate via (TSV) 55 penetrating the substrate R3 to electrically connecting the interconnect structure ML1 and the interconnect structure ML3. In some embodiments, the logic device 30 electrically connects the pixel transistor array 20 through the conductive features (e.g., 511, 512, 513 and 514) of the interconnect structure ML1, the TSV 55, and conductive features (e.g., 531, 532, 533 and 534) of the interconnect structure ML3. In some embodiments, the TSV 55 extends between a metal line feature 514 in the interconnect structure ML1 and a metal line feature 532 in the interconnect structure ML3.

The memory device 61 of the semiconductor structure 4 may be designed for storage of information from the pixel transistor array 20 of the pixel structure 60. In some embodiments, the memory device 61 electrically connects to the pixel transistor array 20 through the interconnect structure ML3. In some embodiments of the semiconductor structure 4, a distance between the memory device 61 and pixel transistor array 20 is less than a distance between the memory device 61 and the logic device 30 or a distance between the memory device 61 and the BSI sensor 10.

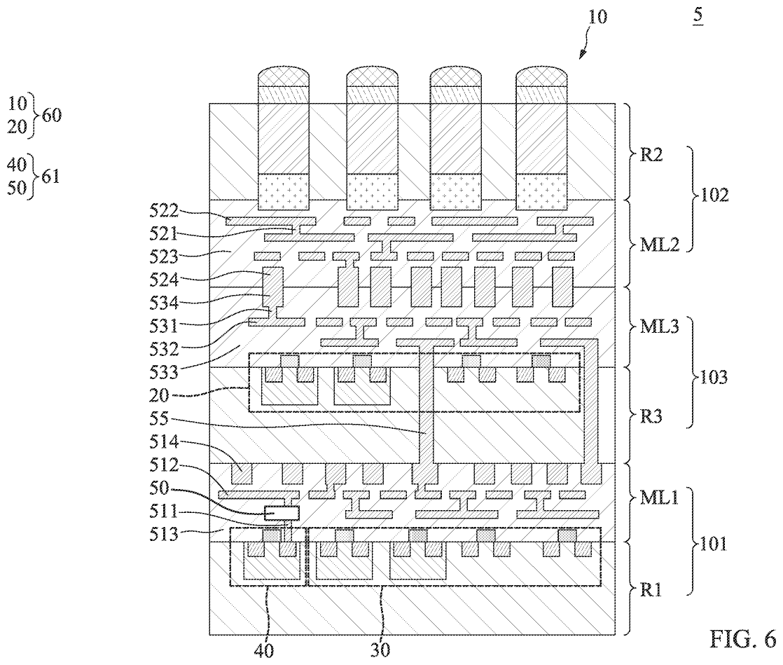

FIG. 6 is a schematic cross-sectional diagram of a semiconductor structure 5 in accordance with some embodiments of the present disclosure. The semiconductor structure 5 can be similar to the semiconductor structure 4 but with a memory device 61 disposed in the first wafer 101 instead of the third wafer 103. In some embodiments, a memory transistor 40 is horizontally aligned with the logic device 30. In some embodiments, the memory transistor 40 is vertically overlapped by a pixel transistor array 20 in the substrate R3 of the wafer 103. In some embodiments, a MRAM unit 50 is disposed in an interconnect structure ML1 of the first wafer 101 and vertically overlaps the memory transistor 40. In some embodiments, the MRAM unit 50 is vertically between the memory transistor 40 and pixel transistor array 20.

The memory device 61 of the semiconductor structure 5 may be designed for storage of information from the logic device 30. In some embodiments, the memory device 61 electrically connects to the logic device 30 through the interconnect structure ML1. In some embodiments of the semiconductor structure 5, a distance between the memory device 61 and logic device 30 is less than a distance between the memory device 61 and the pixel transistor array 20 or a distance between the memory device 61 and the BSI sensor 10.

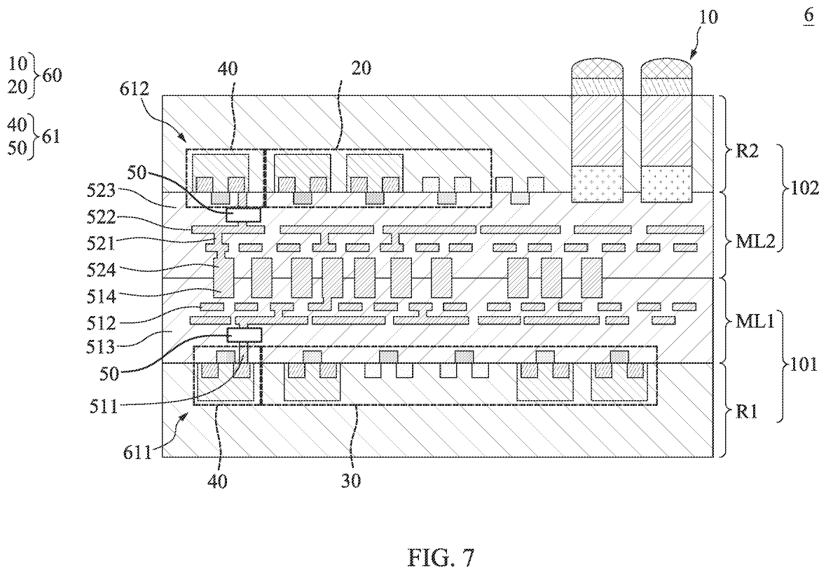

FIG. 7 is a schematic cross-sectional diagram of a semiconductor structure 6 in accordance with some embodiments of the present disclosure. The semiconductor structure 6 is a two-wafer stacking structure. The semiconductor structure 6 can be similar to a combination of the semiconductor structures 2 and 3. A first wafer 101 of the semiconductor structure 6 can be similar to the first wafer 101 of the semiconductor structure 2, and a second wafer 102 of the semiconductor structure 6 can be similar to the second wafer 102 of the semiconductor structure 3. In other words, the semiconductor structure 6 includes a memory device 61 in the first wafer 101 and a memory device 61 in the second wafer 102. For a purpose of illustration, the memory device 61 in the first wafer 101 is referred to as a memory device 611, and the memory device 61 in the second wafer 102 is referred to as memory device 612.

In some embodiments, the memory device 612 electrically connects to the pixel structure 60 through the interconnect structure ML2 for storing information from the pixel structure 60. In some embodiments, the memory device 611 electrically connects to the logic device 30 through the interconnect structure ML1 for storing information from the logic device 30. A position of the memory device 611 in a substrate R1 of the first wafer 101 can be adjusted according to different layout designs. In some embodiments, the memory device 612 vertically overlaps the memory device 611 as shown in FIG. 7. In other embodiments, a vertical projection of the memory device 612 is separated from a vertical projection of the memory device 611. In some embodiments, the memory device 611 is vertically overlapped by the BSI sensor 10. In some embodiments, the memory device 611 is vertically overlapped by the pixel transistor array 20. In some embodiments, a size of a layout of the memory device 611 is substantially equal to a size of a layout of the memory device 612.

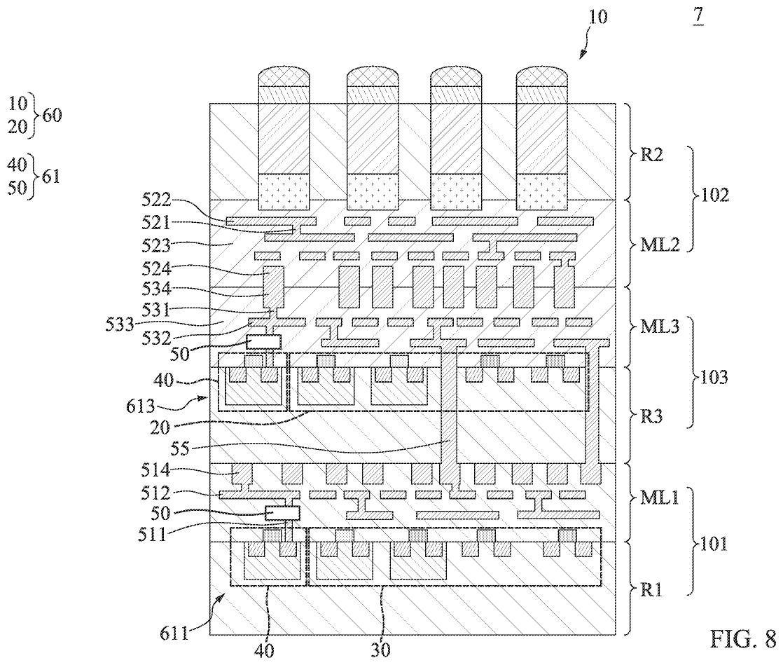

FIG. 8 is a schematic cross-sectional diagram of a semiconductor structure 7 in accordance with some embodiments of the present disclosure. The semiconductor structure 7 is a three-wafer stacking structure. The semiconductor structure 7 can be similar to a combination of the semiconductor structures 4 and 5. A first wafer 101 of the semiconductor structure 7 can be similar to the first wafer 101 of the semiconductor structure 5, and a third wafer 103 of the semiconductor structure 7 can be similar to the third wafer 103 of the semiconductor structure 4. Individual of the second wafers 102 of the semiconductor structures 4 and 5 includes the BSI sensor 10 in the substrates R2, and the second wafer 102 of the semiconductor structure 7 can be similar to the second wafer 102 of the semiconductor structure 4 or 5. In other words, the semiconductor structure 7 includes a memory device 61 in the third wafer 103 and a memory device 61 in the first wafer 101. For a purpose of illustration, the memory device 61 in the first wafer 101 is referred to as a memory device 611, and the memory device 61 in the third wafer 103 is referred to as memory device 613.

In some embodiments, the memory device 613 electrically connects to a pixel transistor array 20 through an interconnect structure ML3 for storing information from the pixel transistor array 20. In some embodiments, the memory device 611 electrically connects to the logic device 30 through an interconnect structure ML1 for storing information from the logic device 30. A position of the memory device 611 in a substrate R1 of the first wafer 101 can be adjusted according to different layout designs. In some embodiments, the memory device 613 vertically overlaps the memory device 611 as shown in FIG. 8. In other embodiments, a vertical projection of the memory device 613 is separated from a vertical projection of the memory device 611. In some embodiments, the memory device 611 is vertically overlapped by the pixel transistor array 20. In some embodiments, the memory device 613 vertically overlaps by the logic device 30. In some embodiments, a size of a layout of the memory device 611 is substantially equal to a size of a layout of the memory device 613.

As the semiconductor industry growth, a demand on high quality and high speed of image throughput has been encountered, and a traditional image sensor is not sufficient to provide high quality and high speed of image throughput. The present disclosure provides a semiconductor structure with integrated MRAM device and BSI sensor can provide improved quality and speed of image throughput.

In accordance with some embodiments of the disclosure, a semiconductor structure is provided. The semiconductor structure includes a substrate, an interconnect structure, a pixel structure, a memory device and a logic device. The interconnect structure is disposed over a front-side of the substrate. The pixel structure includes an image sensor, disposed in a backside of the substrate and configured to receive an optical signal from the backside of the substrate; and a pixel transistor array, disposed in the substrate and adjacent to the image sensor. The memory device includes a memory transistor, disposed in the substrate; and a MRAM unit, disposed in the interconnect structure and over the memory transistor. The logic device is disposed in the substrate and configured to process an electrical signal generated by the optical signal from the image sensor.

In accordance with some embodiments of the disclosure, a semiconductor structure is provided. The semiconductor structure includes a first wafer, a pixel structure, a second wafer, a logic device, and a memory device. The first wafer includes a first substrate and a first interconnect structure. The pixel structure is disposed in the first wafer and includes an image sensor and a pixel transistor array. The image sensor is disposed at a backside of the first substrate and configured to receive an optical signal from a backside of the first substrate. The pixel transistor array is disposed in and at the front-side of the first substrate. The second wafer includes a second substrate and a second interconnect structure. The logic device is disposed in the second substrate and configured to process an electrical signal generated by the optical signal from the image sensor. The memory device includes a memory transistor and a MRAM unit. The memory transistor is disposed in at least one of the first substrate and second substrate. The MRAM unit is disposed in at least one of the first interconnect structure and the second interconnect structure.

In accordance with some embodiments of the disclosure, a semiconductor structure is provided. The semiconductor structure includes a first wafer, an image sensor, a second wafer, a pixel transistor array, a third wafer, a logic device, and a first memory device. The first wafer includes a first substrate and a first interconnect structure. The image sensor is disposed in the first substrate and configured to receive an optical signal from a backside of the first substrate. The second wafer includes a second substrate and a second interconnect structure, wherein a first bonding interface is located between the first interconnect structure and the second interconnect structure. The pixel transistor array is disposed in the second substrate. The third wafer includes a third substrate and a third interconnect structure, wherein a second bonding interface is located between the second substrate and the third interconnect structure. The logic device is disposed in the third substrate and configured to process an electrical signal generated by the optical signal from the image sensor. The first memory device includes a memory transistor and a MRAM unit. The memory transistor is disposed in at least one of the second substrate and third substrate. The MRAM unit is disposed over and electrically connected to the memory transistor.

The foregoing outlines features of several embodiments so that those skilled in the art may better understand aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor structure, comprising:
a substrate;
an interconnect structure, disposed over a front-side of the substrate;
a pixel structure, comprising:
an image sensor, disposed in a backside of the substrate and configured to receive an optical signal from the backside of the substrate; and
a pixel transistor array, disposed in the substrate and adjacent to the image sensor;
a memory device, comprising:
a memory transistor, disposed in the substrate; and
a MRAM unit, disposed in the interconnect structure and over the memory transistor; and
a logic device, disposed in the substrate and configured to process an electrical signal generated by the optical signal from the image sensor.

2. The semiconductor structure of claim 1, wherein the MRAM unit includes a lower electrode, a dielectric layer, a capping layer, and an upper electrode disposed in sequence over the memory transistor, and the lower electrode of the MRAM unit is electrically connected to a drain structure of the memory transistor.

3. The semiconductor structure of claim 1, wherein the memory device is electrically connected to the pixel structure through the interconnect structure for storing information from the pixel structure.

4. The semiconductor structure of claim 1, wherein the memory device is electrically connected to the logic device through the interconnect structure for storing information from the logic device.

5. The semiconductor structure of claim 1, further comprising:
a deep trench capacitor, disposed in the substrate at an elevation of the pixel transistor array, the memory transistor and the logic device.

6. The semiconductor structure of claim 1, wherein the memory transistor is disposed between the pixel transistor array and the logic device.

7. A semiconductor structure, comprising:
a first wafer, including a first substrate and a first interconnect structure;
a pixel structure, disposed in the first wafer, and comprising:
an image sensor, disposed at a backside of the first substrate and configured to receive an optical signal from a backside of the first substrate; and
a pixel transistor array, disposed in and at the front-side of the first substrate;
a second wafer, including a second substrate and a second interconnect structure;
a logic device, disposed in the second substrate and configured to process an electrical signal generated by the optical signal from the image sensor; and
a memory device, comprising:
a memory transistor, disposed in at least one of the first substrate and second substrate; and
a MRAM unit, disposed in at least one of the first interconnect structure and the second interconnect structure.

8. The semiconductor structure of claim 7, wherein the memory device is disposed in the first wafer, and the memory transistor is at an elevation the same as an elevation of the pixel transistor array.

9. The semiconductor structure of claim 8, wherein the memory device in the first wafer vertically overlaps the logic device in the second wafer.

10. The semiconductor structure of claim 7, wherein the memory device is disposed in the second wafer, and the memory transistor is at an elevation the same as an elevation of the logic device.

11. The semiconductor structure of claim 10, wherein the memory device in the second wafer vertically overlaps at least one of the pixel transistor array and the image sensor in the first wafer.

12. The semiconductor structure of claim 7, wherein the pixel structure has a first layout, the memory device has a second layout, and a size of the first layout is greater than a size of the second layout.

13. The semiconductor structure of claim 7, wherein the first interconnect structure is bonded to the second interconnect structure.

14. A semiconductor structure, comprising:
a first wafer, including a first substrate and a first interconnect structure;
an image sensor, disposed in the first substrate and configured to receive an optical signal from a backside of the first substrate;
a second wafer, including a second substrate and a second interconnect structure, wherein a first bonding interface is located between the first interconnect structure and the second interconnect structure;
a pixel transistor array, disposed in the second substrate;
a third wafer, including a third substrate and a third interconnect structure, wherein a second bonding interface is located between the second substrate and the third interconnect structure;
a logic device, disposed in the third substrate and configured to process an electrical signal generated by the optical signal from the image sensor; and
a first memory device, comprising:
a memory transistor, disposed in at least one of the second substrate and third substrate; and
a MRAM unit, disposed over and electrically connected to the memory transistor.

15. The semiconductor structure of claim 14, wherein the first memory device is disposed in the second wafer, the memory transistor is horizontally adjacent to the pixel transistor array, and the MRAM unit is disposed in the second interconnect structure.

16. The semiconductor structure of claim 14, wherein the first memory device is disposed in the third wafer, the memory transistor is horizontally adjacent to the logic device, and the MRAM unit is disposed in the third interconnect structure.

17. The semiconductor structure of claim 14, further comprises a second memory device, wherein the first memory device and the second memory device are respectively disposed in the second wafer and the third wafer.

18. The semiconductor structure of claim 17, wherein the first memory device is vertically aligned with the second memory device.

19. The semiconductor structure of claim 17, wherein the second memory device comprises a MRAM unit and a memory transistor.

20. The semiconductor structure of claim 14, further comprising at least a through via disposed in the second substrate, wherein the second interconnect structure and the third interconnect structure are electrically connected by the through via.
